(19) United States
(12) Patent Application Publication
(10) Pub. No.: US 2026/0293055 A1
(43) Pub. Date: Sep. 24, 2026

(54) ELECTRICAL COMPONENT AND STEERING DEVICE USING THE ELECTRICAL COMPONENT

(71) Applicant: TOYODA GOSEI CO., LTD., Kiyosu-shi (JP)

(72) Inventors: Kazuma MURAMATSU, Aichi (JP); Akitoshi NAGANAWA, Aichi (JP); Masaaki MORI, Aichi (JP); Yuko SAKURAI, Aichi (JP); Tsukasa KITAZAWA, Aichi (JP); Norifumi HATTORI, Aichi (JP); Eiki KAWANO, Aichi (JP)

(21) Appl. No.: 19/550,787

(22) Filed: Feb. 26, 2026

(30) Foreign Application Priority Data
Mar. 19, 2025 (JP) 2025-045343

(51) Int. Cl. H05K 7/20; B62D 1/06

(52) U.S. Cl. CPC H05K 7/2039; B62D 1/065; H05K 7/20854

(57) ABSTRACT

An electrical component has a high-temperature part that reaches a predetermined temperature or higher, an accommodation member that accommodates the high-temperature part, and a heat radiation sheet that transfers heat from the high-temperature part, by radiation, to a radiant heat destination member different from the accommodation member. It is possible to increase the design freedom of a heat dissipation structure in the electrical component and to easily realize heat dissipation.

### CROSS-REFERENCE TO RELATED APPLICATIONS

This application is based on and claims priority under 35 USC 119 from Japanese Patent Application No. 2025-045343 filed on March 19, 2025, the entire content of which is incorporated herein by reference.

### TECHNICAL FIELD

The present disclosure relates to an electrical component and a steering device using the electrical component.

### BACKGROUND ART

In recent years, it is not uncommon for various electronic components to be arranged in a confined space such as a handle portion of a steering device. In such a case, heat generated from the electronic components is dissipated to the outside by heat conduction to prevent excessive temperature rise of the electronic components and a space housing the electronic components. For example, in JP7327321B, heat from light emitting diodes (hereinafter, LEDs) is dissipated to a core metal of a steering wheel through a heat conduction member, thereby avoiding temperature rise inside a confined case of the steering wheel.

JP7327321B is an excellent invention in which the temperature rise inside the case forming the steering wheel is avoided by dissipating the heat from the LEDs to the core metal of the steering wheel. However, when attempting to dissipate the heat by heat conduction, it is necessary to ensure reliable contact between the object whose temperature rise is to be suppressed and the heat dissipation side via a heat conduction member, which may, in some cases, risk limiting the design freedom such as the arrangement of the electronic components.

### SUMMARY

(1) A first aspect of the present disclosure relates to an electrical component (200, 200B-200E) having a high-temperature part (31) that reaches a predetermined temperature or higher. The electrical component has an accommodation member (40, 40C, 40E) that accommodates the high-temperature part, and a heat radiation sheet (300-304) that transfers heat from the high-temperature part, by radiation, to a radiant heat destination member (50, 50C) different from the accommodation member. According to the first aspect, the electrical component has no need for direct contact between the high-temperature part and the radiant heat destination member, thereby increasing the design freedom in the electrical component.
(2) A second aspect of the present disclosure relates to a steering device (100). The steering device has a handle portion (110, 110B-110E) for steering operation, and the above-described electrical component. The radiant heat destination member constitutes a part of the handle portion. According to the second aspect ,it is possible to increase the design freedom in the steering device.

In this specification, terms generally follow the definitions below. When terms are used outside the following definitions, an explanation will be provided.

Light: Electromagnetic waves including not only visible light but also infrared electromagnetic waves (infrared rays) up to far-infrared on the long wavelength side, and near-ultraviolet electromagnetic waves (near-ultraviolet rays) on the short wavelength side. In terms of wavelength range, electromagnetic waves from approximately 10 μm to 200 nm are collectively referred to as light. Infrared rays and ultraviolet rays may sometimes be referred to as infrared light and ultraviolet light, respectively, depending on the case.

Light source: Something that emits light. This includes light bulbs, LEDs, organic ELs, etc., regardless of the mechanism of light emission.

Light emission: The emission of light from a light source. This is regardless of the presence or degree of directivity, intensity, wavelength, etc.

Emission: Radiation of light with a certain directivity from a relatively narrow region such as a point light source or a small aperture.

Incidence: Light reaching a boundary surface between an object and its exterior. In this specification, it may refer to light entering the interior of an object through a boundary surface, as a counterpart to "outgoing emission."

Outgoing emission: As a counterpart to "incidence," it refers to light from inside an object exiting to the outside through a boundary surface between the object and its exterior.

Outgoing light: Light exiting from an object and traveling in a specific direction.

Incident light: Light traveling toward an object from a specific direction and entering the interior of the object.

Radiation and thermal radiation: The release of electromagnetic waves including light or particle beams from an object is called "radiation." The radiation of electromagnetic waves including light is called "thermal radiation." When heat transfers to the outside by radiation, it is called "heat radiation," and heat that transfers by electromagnetic wave radiation may be called "radiant heat."

Illumination: Changes in brightness or hue in a certain area due to light. Changes in brightness or hue may correspond to the transmission of certain information, or may be decorative, or may be for the purpose of lighting or irradiation with light, etc.

### BRIEF DESCRIPTION OF DRAWINGS

Exemplary embodiments of the present invention will be described in detail based on the following figures, wherein:

FIG. 1 is a plan view showing an external shape of a steering device with a transmission component of an embodiment attached;

FIG. 2 is a plan view showing an external shape of the steering device in a state in which a cover member, a light guiding member, and an accommodation member are removed;

FIG. 3 is a first exploded perspective view showing a detailed configuration of an illumination device with an electrical component incorporated;

FIG. 4 is a second exploded perspective view showing a detailed configuration of the illumination device;

FIG. 5 is an explanatory diagram showing the arrangement of a heat radiation sheet in the V-V cross-section of the steering device shown in FIG. 2;

FIG. 6 is an explanatory diagram showing the structure of the heat radiation sheet;

FIG. 7 is an explanatory diagram showing the arrangement of a heat radiation sheet in a second embodiment;

FIG. 8 is an explanatory diagram showing the arrangement of a heat radiation sheet in a third embodiment;

FIG. 9 is an explanatory diagram showing the arrangement of a heat radiation sheet in a fourth embodiment; and

FIG. 10 is an explanatory diagram showing the arrangement of a heat radiation sheet in a fifth embodiment.

### DESCRIPTION OF EMBODIMENTS

### A. First Embodiment

### A1 Overall Configuration of Steering Device 100

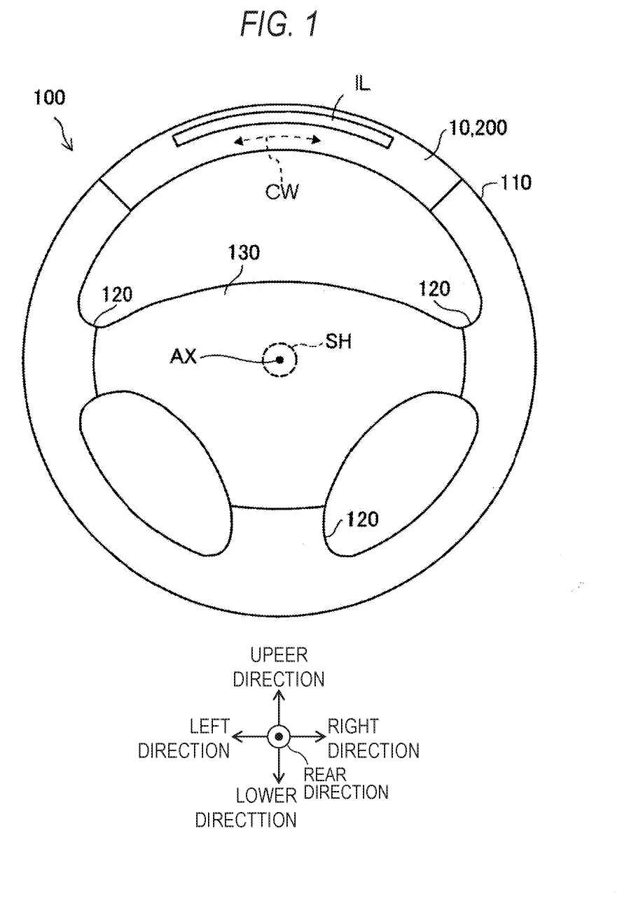

FIG. 1 is a plan view showing an external shape of a steering device 100 in a state in which an illumination device 200 as an embodiment of the present disclosure is attached. The steering device 100 is disposed in a driver's seat of a vehicle and used. Examples of the vehicle include an engine-powered vehicle, a hybrid electric vehicle (HEV), a plug-in hybrid electric vehicle (PHEV), a battery electric vehicle (BEV), a fuel cell vehicle (FCV), and the like. Of course, it can also be implemented as a steering device for a moving body other than the vehicle, such as a senior car, a two-wheeled vehicle, a ship, and the like.

The steering device 100 is a part of a steering apparatus operated by a driver of the vehicle. FIG. 1 shows the steering device 100 in a state connected to a steering shaft SH in the vehicle and in a state for driving the vehicle straight ahead (hereinafter also referred to as a "reference state"). Also, FIG. 1 shows the external configuration of the steering device 100 on the side facing the driver (the "rear" side described later). The steering device 100 is configured to be rotatably operated about an axis AX of the steering shaft SH. The rotation of the steering device 100 is transmitted to a steering gear box (not shown) via the steering shaft SH. Although the steering device 100 of this embodiment has an overall substantially annular shape, this shape may be replaced with any shape such as a polygonal shape or an elliptical shape, and may also be an asymmetrical shape such as a so-called D-shape. Furthermore, the shape of the portion gripped for steering is not limited to an annular shape, but may be any shape formed by multiple parts provided at positions separated from each other.

In this embodiment, the direction along the axis AX of the steering shaft SH is referred to as the "front-rear direction" (forward direction and rearward direction) in correspondence with the traveling direction of the vehicle. Also, among the directions orthogonal to the axis AX, the direction that overlaps with the vertical direction (vertically upward and vertically downward) as viewed from the driver is referred to as the "upper-lower direction." Furthermore, among the directions orthogonal to the axis AX, the direction parallel to the left-right direction (width direction) of the vehicle is referred to as the "left-right direction." In this case, left and right correspond to the directions as viewed from the driver's seat.

The steering device 100 is rotated clockwise or counterclockwise as viewed from the driver's seat for steering. Therefore, in the following description, when explaining the arrangement of each component in the steering device 100 using the terms "upper-lower direction" and "left-right direction," each direction is referred to assuming that the steering device 100 is in the reference state. The "front-rear direction" does not change with the steering state of the steering device 100.

The steering device 100 includes a ring-shaped grip portion 110, a boss portion 130 disposed in approximately the center portion of the grip portion 110, three spoke portions 120, and an illumination device 200 as an electrical component disposed on a part of the grip portion 110. As described later, the illumination device 200 is provided with light-emitting elements such as LEDs as light sources, and light from the light-emitting elements is guided inside the illumination device 200, making illumination visible from the outside in a part of the region of the grip portion 110. This region is called the illumination region IL.

The grip portion 110 is gripped by the driver when operating the steering device 100. Since it is the part gripped by the driver, the grip portion 110 may sometimes be referred to as a "handle portion" or "handle material." In this embodiment, the shape of the grip portion 110 is substantially annular. The central axis of the grip portion 110 coincides with the axis AX of the steering shaft SH. The arrangement of components in the illumination device 200 placed inside this grip portion 110 follows the shape of the grip portion 110. Therefore, in the following description, the direction along the ring of the substantially annular grip portion 110 may be referred to as the ring direction CW. The ring direction CW is shown in FIG. 1 for illustration purposes.

As described later, the grip portion 110 of this embodiment is configured by stacking multiple members in the thickness direction. The outermost layer is formed by a skin layer (skin layer 80 described later) formed of leather material. Although not shown in FIG. 1, a recess (recess C1 described later) is formed in a part of the grip portion 110 positioned at the upper side in the reference state to accommodate a part of the illumination device 200. A part of the illumination device 200 is accommodated in the recess C1. In other words, the illumination device 200 is fitted into the recess C1. And the opening of the recess C1 is closed by the illumination device 200.

The three spoke portions 120 connect the grip portion 110 and the boss portion 130. The boss portion 130 corresponds to the connection part for connecting the steering device 100 to the steering shaft SH. Inside the boss portion 130, a folded airbag and an inflator, both not shown, are accommodated. Furthermore, various sensor devices such as a temperature control circuit constituting a heater device, a sensor for detecting the user's grip on the grip portion 110, and a sensor for detecting room temperature may also be accommodated inside the boss portion 130. Various operation buttons for operating navigation devices, audio devices, etc. mounted in the vehicle may be provided on the three spoke portions 120 and the boss portion 130.

The illumination device 200 includes a light source that radiates light. In this embodiment, the light radiating from the light source of the illumination device 200 is visible light and infrared rays (infrared light). The illumination device 200 can notify various information to the driver by changing the brightness of visible light in the illumination region IL. For example, by changing the brightness of the entire or part of the illumination region IL, or by changing its hue, various information can be notified to the driver. Specifically, by making the entire or part of the illumination region IL red, the driver can be prompted to grip the steering device. The changes in brightness or hue of the illumination region IL by the illumination device 200 are not limited to those intended for notifying such information, but may be merely decorative or intended to awaken the driver from drowsiness. Also, the light radiating from the light source of the illumination device 200 is not limited to visible light, but may be infrared rays. In this embodiment, as described later, both visible light and infrared rays radiate. The infrared rays are emitted from the illumination region IL toward the driver's seat direction. The infrared rays are irradiated onto the driver's body and used to capture images of parts of the driver's body. By irradiating infrared rays from the steering device 100 to the driver in a dark vehicle interior at night, it is possible to facilitate capturing images of the driver with an infrared camera without causing glare to the driver.

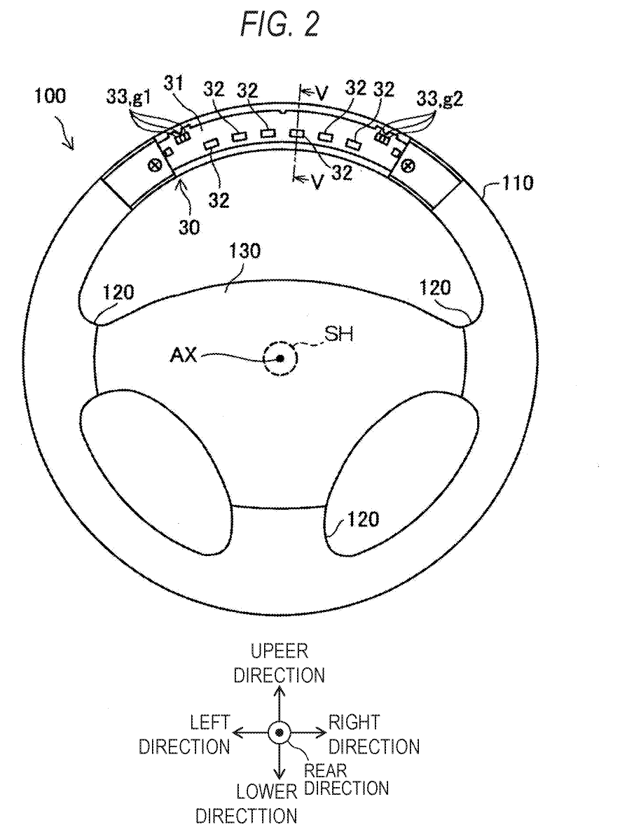

FIG. 2 is a plan view showing an external shape of the steering device 100 in a state in which a cover member 10, a light guiding member 20, and an accommodation member 40 are removed. As described later, in the illumination device 200, the cover member 10 having light transmission for visible light and infrared rays is disposed at a position facing the driver, and the light guiding member 20 and the accommodation member 40 described later are disposed on the forward side of the cover member 10. FIG. 2 schematically shows the steering device 100 in the state in which the cover member 10, the light guiding member 20, and the accommodation member 40 are removed.

As shown in FIG. 2, when the cover member 10, the light guiding member 20, and the accommodation member 40 are removed, a light emitting portion 30, which is one of the elements constituting the illumination device 200, is exposed. The light emitting portion 30 includes a substrate 31 and a plurality of light emitting elements provided on the surface of the substrate 31. The "plurality of light emitting elements" in this embodiment include a plurality of first LEDs 32 and a plurality of second LEDs 33 as light sources. The substrate 31, as viewed from the driver, has an external shape of an arc curved along the circumferential direction of the grip portion 110 (hereinafter also simply referred to as the "circumferential direction") and in a strip shape. Hereinafter, the radial direction of the grip portion 110 (the direction orthogonal to the axis AX) may also be simply referred to as the "radial direction." The plurality of first LEDs 32 are arranged along the circumferential direction at predetermined distances from each other at positions close to the lower edge of the rear surface of the substrate 31. The first LEDs 32 radiate visible light. In this embodiment, visible light LEDs capable of emitting red light, green light, and blue light are used as the first LEDs 32.

In contrast, the plurality of second LEDs 33 radiate light in the infrared region. The plurality of second LEDs 33 form two groups g1 and g2 that are arranged apart from each other. Each group g1, g2 consists of multiple second LEDs 33 adjacent to each other in the circumferential direction. Both groups g1 and g2 are arranged at positions close to the upper edge of the rear surface of the substrate 31. These two groups g1 and g2 are arranged apart from each other so as to sandwich the plurality of first LEDs 32 when viewed along the circumferential direction.

### A2 Detailed Configuration of the Illumination Device 200

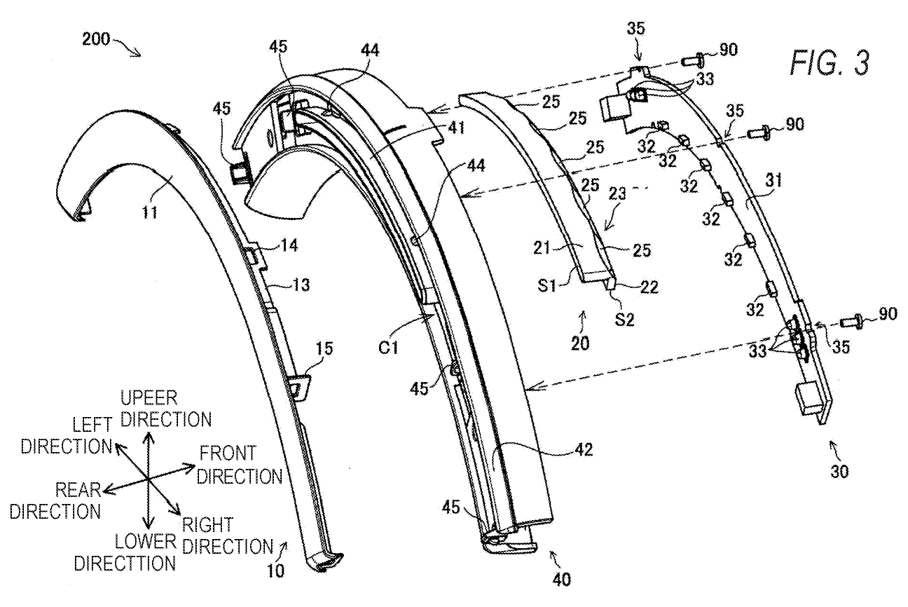

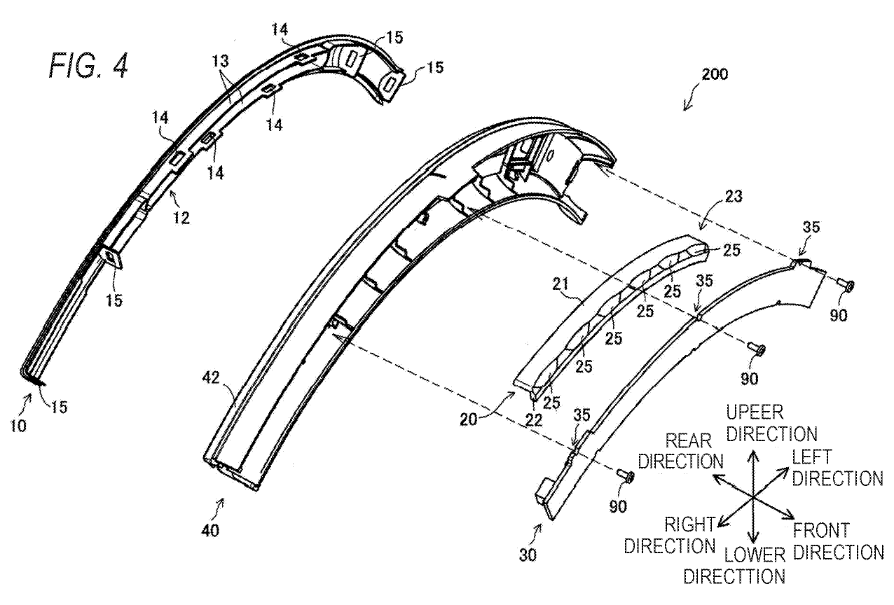

FIG. 3 is a first exploded perspective view showing a detailed configuration of the illumination device 200. FIG. 4 is a second exploded perspective view showing a detailed configuration of the illumination device 200. FIG. 3 corresponds to an exploded perspective view looking approximately from the rear side toward the front side of the illumination device 200. FIG. 4 corresponds to an exploded perspective view looking approximately from the front side toward the rear side of the illumination device 200.

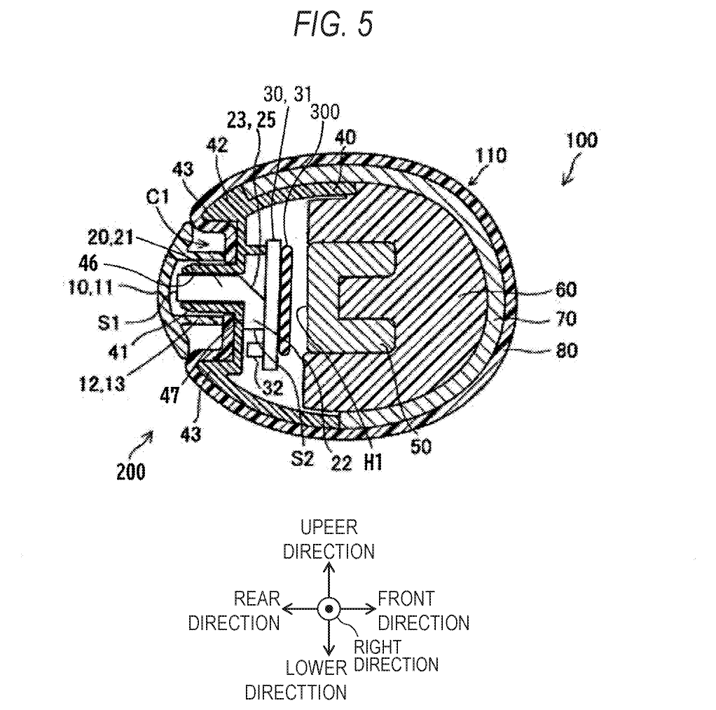

FIG. 5 is a cross-sectional view showing the V-V cross-section in FIG. 2, that is, a cross-section of the steering device 100. FIG. 5 shows the cross-section at the position where the first LED 32 of the illumination device 200 exists as shown in FIG. 2, but for ease of illustration, hatching indicating cross-sections is not applied to the light guiding member 20, the substrate 31, and the first LED 32.

As shown in FIGS. 3 and 4, the illumination device 200 includes, in addition to the above-mentioned light emitting portion 30, a cover member 10, a light guiding member 20, and a accommodation member 40. The illumination device 200 has a structure in which the light guiding member 20, the light emitting portion 30, and the cover member 10 are assembled together in the front-rear direction with the accommodation member 40 interposed between them.

As shown in FIGS. 3 and 4, the cover member 10 includes an outer surface forming portion 11, a surrounding portion 12, and a plurality of engagement walls 15. The outer surface forming portion 11 shown in FIG. 3 forms the outer surface of the steering device 100 continuously with the skin layer 80 as shown in FIG. 5. The outer surface forming portion 11, similar to the substrate 31 described above, has an external shape of an arc curved along the circumferential direction of the grip portion 110 and in a strip shape as viewed from the driver. The outer surface forming portion 11 has transmission for visible light and infrared rays. In this embodiment, the outer surface forming portion 11 has a transmission rate of approximately 25% for visible light and approximately 90% for infrared rays. The transmission rates for visible light and infrared rays may be any value higher than 0%. In this embodiment, the outer surface forming portion 11 is formed of black transparent synthetic resin to match the black skin layer 80. The outer surface forming portion 11 has, in addition to a function of protecting the light emitting portion 30, a function of limiting a region through which the visible light emitted from the first LEDs 32 as light sources is transmitted (in other words, a function of masking regions other than the illumination region), and a function of deflecting an emission direction of the infrared rays emitted from the second LEDs 33 to be directed to the upper side on the rear direction side which is a driver side. Furthermore, the outer surface forming portion 11 may have a function of scattering the emission direction of visible light incident from the first LEDs 32 when it is emitted to the outside.

The surrounding portion 12 is provided on the front direction side surface (inner surface) of the outer surface forming portion 11 as shown in FIG. 4. In a state in which the illumination device 200 is assembled (hereinafter, also simply referred to as an "assembled state"), the surrounding portion 12 is disposed to surround a support portion 41 protruding from the recess C1 of the accommodation member 40 shown in FIGS. 3 and 5 toward the rear direction side, and a first light guiding portion 21 (to be described later) corresponding to a part of the light guiding member 20 accommodated in the support portion 41 over the entire periphery. The recess C1 has a groove-like structure that opens on the front direction surface of the accommodation member 40 and extends along the circumferential direction. A protruding portion 13 of the surrounding portion 12, which corresponds to a side wall along the radial direction, protrudes from the front direction side surface, in other words, the inner surface of the outer surface forming portion 11 in the depth direction of the recess C1. The "depth direction of the recess C1" substantially coincides with the front-rear direction in this embodiment, as is clear from FIGS. 3 and 5. As shown in FIG. 4, a plurality of engagement holes 14 are formed in the protruding portion 13. In the assembled state, engagement claws 44 (see FIG. 3) provided on the outer peripheral surface of the support portion 41 of the accommodation member 40 engage with the engagement holes 14. This engagement is achieved through a series of actions in which, when the cover member 10 is pushed into the accommodation member 40, the protruding portion 13 elastically deforms along the shape of the engagement claws 44, passes over the engagement claws 44 and returns to its original shape, thereby causing the engagement claws 44 to fit into the engagement holes 14. A structure that fixes one member to another member by utilizing such elastic deformation of the members is called a snap fit. Similarly, the plurality of engagement walls 15 provided on the cover member 10, as shown in FIG. 4, have a wall-like elastically deformable shape protruding in the forward direction, and the engagement holes provided on the engagement walls 15 and the engagement claws provided on the engagement walls 45 snap fit together. This also fixes the cover member 10 to the accommodation member 40.

The light guiding member 20 guides the light (visible light) emitted from the first LEDs 32 to the cover member 10. In the present embodiment, the light guiding member 20 is made of a polycarbonate (PC) resin. Instead of PC resin, it may be formed of acrylic resin. As shown in FIGS. 3 to 5, the light guiding member 20 has an external shape with a cross-sectional shape along the axis AX that is substantially L-shaped. In addition, the light guiding member 20 has an arc-like external shape in accordance with disposed positions of the plurality of first LEDs 32 when viewed by the driver.

As shown in FIGS. 3 to 5, the light guiding member 20 includes a first light guiding portion 21, a second light guiding portion 22, and a deflection portion 23. The first light guiding portion 21 has an emission surface S1 through which visible light is emitted from the light guiding member 20 to the cover member 10. The first light guiding portion 21 has a predetermined length along a direction (hereinafter also referred to as a "first direction") from the surface of the substrate 31 toward the cover member 10. The first direction is parallel to the forward direction. The second light guiding portion 22 has an incident surface S2 on which the visible light output from the first LEDs 32 is incident. As shown in FIG. 5, the incident surface S2 is positioned above the first LEDs 32. Therefore, visible light from the first LEDs 32 is incident on the incident surface S2 in the upper direction. The second light guiding portion 22 has a predetermined length along a direction (hereinafter also referred to as a "second direction") intersecting the first direction. The second direction corresponds to the upper direction and approximately upper direction in the state shown in FIG. 5. In this embodiment, the first direction and the second direction are orthogonal to each other, but they may be at an angle other than orthogonal.

The deflection portion 23 changes the direction of light incident from each first LED 32 from roughly the second direction to the first direction by total reflection at a boundary surface provided on a part of the outer periphery of the light guiding member 20, while also scattering the light to spread over a predetermined range in the adjacent direction of the plurality of first LEDs 32, that is, in the circumferential direction CW. To achieve such a change in direction of light from the first LEDs 32, the boundary surface provided on a part of the outer periphery of the light guiding member 20 has a concave shape that is recessed in the circumferential direction CW corresponding to each first LED 32, as shown in FIG. 4. This boundary surface is called a diffusion reflection portion 25.

The detailed shape of the light guiding member 20 including the diffusion reflection portion 25 will be described below. On the optical axis passing through the center of each first LED 32, as shown in FIG. 5, the diffusion reflection portion 25 is formed as a reflection surface inclined at approximately 45 degrees to the first direction and the second direction on a part of the outer peripheral surface of the light guiding member 20, specifically at the portion where the first light guiding portion 21 and the second light guiding portion 22 are connected. As already explained, the diffusion reflection portion 25 has a concave shape in the circumferential direction CW, but it is inclined at approximately 45 degrees to the first direction and the second direction even away from the optical axis passing through the center of the first LED 32. Therefore, the visible light guided by the second light guiding portion 22 is reflected by the diffusion reflection portion 25. The visible light that enters the second light guiding portion 22 from the incident surface S2 and travels upward (in the second direction) is almost totally reflected at the diffusion reflection portion 25 of the deflection portion 23, thereby changing its traveling direction to the forward direction (the first direction), and is guided to the first light guiding portion 21.

As shown in FIG. 4, a plurality of diffusion reflection portions 25 are formed in the deflection portion 23 corresponding to each first LED 32. Each diffusion reflection portion 25 is positioned at a position corresponding to the front of each first LED 32, that is, on the optical axis of the first LED 32. Each diffusion reflection portion 25 has a recessed structure formed by partially chamfering the deflection portion 23. Specifically, each diffusion portion 25 has a recessed structure in which a position corresponding to the first LED 32 in the front direction is most recessed and the depth gradually decreases toward positions corresponding to the adjacent first LEDs 32 along the circumferential direction CW. Also, the width of each diffusion reflection portion 25, that is, the dimension in the upper-lower direction, is largest at the position corresponding to the upper direction (more precisely, the direction toward the radially outer side) of the first LED 32, and gradually decreases toward positions corresponding to the adjacent first LEDs 32 along the circumferential direction CW. With such a structure of each diffusion reflection portion 25, the visible light radiating from each first LED 32 along the second direction with a predetermined directivity is scattered in the circumferential direction CW and the upper-lower direction when its traveling direction is changed to the first direction at the deflection portion 23. As shown in FIG. 5, in the assembled state, the first light guiding portion 21 is accommodated in the recess C1. On the other hand, in the assembled state, the second light guiding portion 22 and the deflection portion 23 are located on the front direction side of the accommodation member 40, and are not accommodated in the recess C1.

The accommodation member 40 accommodates and holds the light guiding member 20 and the light emitting portion 30 attached to its front direction side, and holds the cover member 10 attached to its rear direction side. Details of an attachment state of the accommodation member 40, the light guiding member 20, and the light emitting portion 30 (the substrate 31) will be described later. As shown in FIGS. 3 and 4, the accommodation member 40 has an external shape of an arc curved along the circumferential direction CW and in a strip shape as viewed from the driver. In this embodiment, the accommodation member 40 is configured as a single component formed of ABS resin. Instead of ABS resin, or in addition to ABS resin, it may be configured as a single component formed of PC resin. It may also be configured as a composite component combining multiple components. As described above, a recess C1 continuous in the circumferential direction CW is formed on the rear direction side surface of the accommodation member 40. As shown in FIGS. 3 to 5, on the front direction side surface of the accommodation member 40, covering portions 42 continuous in the circumferential direction CW are provided on the upper direction side and the lower direction side across the recess C1. The cross-sectional shape of the outer surface of the covering portion 42, as shown in FIG. 5, has a shape in which the angle between the surface existing in the upper direction and the surface existing in the lower direction across the top portion 43 is acute. The covering portion 42 is covered by the skin layer 80 to be described later.

In the recess C1, through holes 46 penetrating in the thickness direction are formed in the portion corresponding to the light guiding member 20. As shown in FIG. 5, the first light guiding portion 21 of the light guiding member 20 is inserted into these through holes 46. As shown in FIGS. 3 and 5, in the recess C1, the aforementioned support portion 41 is provided so as to surround the through holes 46 into which the first light guiding portion 21 is inserted. The support portion 41, similar to the surrounding portion 12 of the cover member 10 shown in FIG. 4, is formed to protrude in the rear direction so as to surround the through holes 46 and the side surface of the first light guiding portion 21 inserted into these through holes 46 over the entire periphery. As shown in FIG. 3, the support portion 41 has an external shape of a flattened cylindrical shape curved in an arc. As described above, a plurality of engagement claws 44 are provided on the outer peripheral surface of the support portion 41, and these engagement claws 44 engage with the engagement holes 14 of the cover member 10 in the assembled state. The support portion 41 suppresses positional deviation of the light guiding member 20 including the first light guiding portion 21 in the upper-lower direction and the left-right direction.

The first LEDs 32, second LEDs 33, and other components of the illumination device 200 described above are mounted on the substrate 31 along with other electronic components. A power supply cable and a signal cable are connected to the substrate 31. The power supply cable is a cable for supplying necessary power from an external source, for example, from the vehicle body. The signal cable is a cable for exchanging control signals between the electronic control unit (ECU) on the vehicle side and the substrate 31. Illustrations of these cables are omitted. The control signals include signals for controlling the blinking of the first LEDs 32, second LEDs 33, and so on. The exchange of control signals may be performed by short-range communication such as Bluetooth® (registered trademark), and power supply may be performed by non-contact power supply utilizing magnetic coupling or the like.

When the first LEDs 32 and second LEDs 33 are illuminated in response to control signals, since the light emission efficiency of the first LEDs 32 and others is not 100%, the first LEDs 32 and others generate heat from energy not used for light emission, and this heat is transferred to the substrate 31 on which the first LEDs 32 and others are mounted. As a result, the temperature of the substrate 31 rises. Therefore, the temperature of the first LEDs 32, second LEDs 33, and the substrate 31 on which these LEDs are mounted becomes a high-temperature part with a higher temperature than surrounding components, for example, the cored bar 50 to be described later. In order to reduce the temperature of this substrate 31, in this embodiment, a heat radiation sheet 300 is adhered to the back of the substrate 31, which is the high-temperature part, using an adhesive having insulating properties. Details of the heat radiation sheet 300 will be described later.

### A3 Detailed Configuration of the Grip Portion 110

The structure of the grip portion 110 will be explained in detail. As already explained, the illumination device 200 is accommodated in the grip portion 110, but the illumination device 200 is provided only in a part of the upper direction (the position shown as the illumination region IL in FIG. 1) when the steering device 100 is in the reference state, and is not provided in other regions. The cross-sectional configuration of the portion where the illumination device 200 is not installed is similar to the cross-sectional configuration of the portion where the illumination device 200 is installed as shown in FIG. 5, except that the illumination device 200 is not installed.

As shown in FIG. 5, the grip portion 110, although with or without the above illumination device 200, includes a cored bar 50, a core portion 60, an element layer 70, and an outer skin layer 80 throughout its entire periphery. In this embodiment, the cored bar 50 is a component different from the accommodation member 40 and functions as a radiant heat destination member that receives heat transferred from the high-temperature part, but this mechanism will be explained in detail later.

The cored bar 50 is made of metal and is a component that forms the skeleton of the grip portion 110. In this embodiment, the cored bar 50 is made of aluminum alloy. Instead of aluminum alloy, the cored bar 50 may be formed of any type of metal such as magnesium alloy or steel. The core portion 60 is arranged to cover the entire cored bar 50 except for its rear direction surface H1, and forms the core of the grip portion 110. The core portion 60 is formed of a soft synthetic resin having cushioning properties. Specifically, in this embodiment, the core portion 60 is formed of a soft foam material such as foamed polyurethane. The element layer 70 partially covers the core portion 60.

The element layer 70 is a layer provided with heating wires constituting a heater device and electrodes for detecting gripping. For example, it is formed of conductive fabric with surface treatment such as carbon coating or metal plating applied to fabric. As shown in FIG. 5, in the portion of the grip portion 110 where the illumination device 200 is installed, the element layer 70 also covers a part of a base member. The outer surface of the element layer 70 and the outer surface of a part of the accommodation member 40 form a continuous curved surface. The outer skin layer 80 continuously covers the outer surface of the element layer 70, the outer surface of the covering portion 42 of the accommodation member 40, and the inside of the recess C1 of the accommodation member 40. As shown in FIG. 5, the end portion of the leather material constituting the outer skin layer 80 is accommodated in the recess C1. The outer skin layer 80 is formed of leather material. In this embodiment, the leather material is composed of natural leather such as top leather or split leather divided from top leather. The leather material may be composed of any type of leather material such as synthetic leather or artificial leather instead of natural leather. Also, the material of the outer skin layer 80 may be either a light-shielding material that does not transmit light or a light-transmitting material that transmits light. When a light-transmitting material that transmits light from the first LEDs 32 and the second LEDs 33 is used as the outer skin layer 80, the outer skin layer 80 may be arranged to cover the illumination device 200. In this case, the outer skin layer 80 may have its ends sewn together, and the sewn ends may be accommodated in a groove-shaped recess (for example, recess C1) provided along the circumferential direction of the grip portion 110. The groove-shaped recess may be provided at any position, such as on the back side (front direction side) of the grip portion 110 as viewed by the user of the steering device 100.

The components of the above-described steering device 100 are assembled generally in the following procedure. First, the cover member 10, the light guiding member 20, the light emitting portion 30, and the accommodation member 40 are each prepared. Then, the light guiding member 20 and the light emitting portion 30 are attached to the back surface (the front direction side in the assembled state) of the accommodation member 40. The light guiding member 20 and the light emitting portion 30 are fixed to the accommodation member 40 by engaging three screws 90 shown in FIGS. 3 and 4 with screw holes (not shown) provided in the accommodation member 40 while accommodating them in notches 35 provided in the upper edge portion of the substrate 31. The assembly of the light guiding member 20 and the light emitting portion 30 attached to the accommodation member 40 will hereinafter be referred to as a subassembly.

The subassembly is joined with the cored bar 50 side. For this purpose, first, the core portion 60 and the element layer 70 are formed around the cored bar 50 by a method such as two-color molding. Hereinafter, the component obtained in this manner will be referred to as a "handle material." A leather material is wrapped around the outer surface of the component integrated with the handle material by fastening the subassembly to the cored bar 50 using screws (not shown), thereby forming the outer skin layer 80. The outer skin layer 80 may be formed, for example, by wrapping multiple parts of leather material in the circumferential direction. Then, adhesive is applied to the wall surface of the recess C1, the end portion of the outer skin layer 80 is bent along the shape of the covering portion 42 and accommodated in the recess C1, and this end portion is adhered to the wall surface of the recess C1. Then, the cover member 10 is fitted into the recess C1. The cover member 10 is fixed to the accommodation member 40 by the aforementioned snap fit. The steering device 100 of this embodiment is formed by connecting the grip portion 110 thus formed to the boss portion 130 via the spoke portion 120. The method and procedure for forming the steering device 100 are not limited to this, and appropriate methods and procedures may be adopted according to the material, structure, etc. of each component.

### A4 Configuration and Arrangement of the Heat Radiation Sheet 300 and Heat Dissipation Mechanism

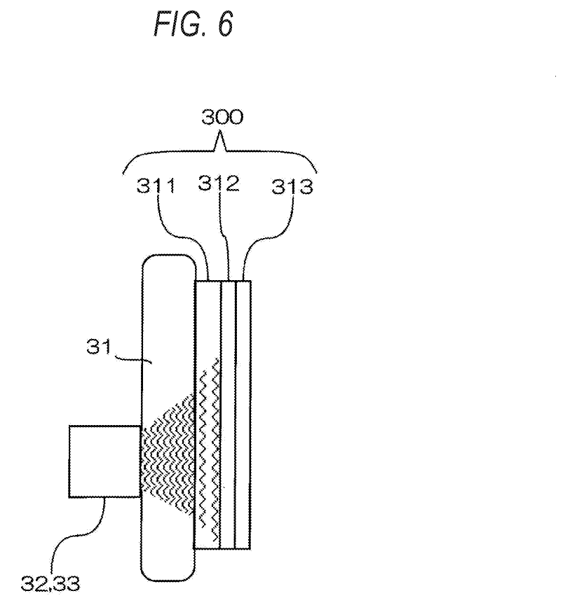

In this embodiment, as shown in FIG. 5, a heat radiation sheet 300 is attached to the back surface (front direction side) of the substrate 31 using an adhesive. A heat radiation silicone sheet or the like can be used as the heat radiation sheet 300. An example of the configuration of the heat radiation sheet 300 is shown in FIG. 6. As shown, the heat radiation sheet 300 has a configuration in which an aluminum layer 312 is sandwiched between a heat conduction layer 311 and a heat radiation layer 313. This heat radiation sheet 300 may be attached not to the entire back surface of the substrate 31 but to a part thereof. Also, instead of using an adhesive, it may be fixed in contact with the substrate 31 using fixing members such as screws. Alternatively, a material with high thermal conductivity, such as a sheet or pipe made of aluminum or copper, may be placed between the substrate 31. In other words, the substrate 31 and the heat radiation sheet 300 should be joined in a manner that allows heat transfer to occur quickly.

The heat conduction layer 311 of the heat radiation sheet 300 has insulating properties and efficiently conducts heat from the heat source (in this case, the substrate 31) to the aluminum layer 312. The heat radiation layer 313, which becomes hot due to heat conduction through the aluminum layer 312, radiates electromagnetic waves to the outside with high efficiency. Due to this radiation, the temperature of the heat radiation sheet 300 decreases, and as a result, the temperature of the substrate 31 also decreases by several to more than ten degrees compared to when there is no heat radiation sheet 300.

The heat radiating from the heat radiation sheet 300 by electromagnetic waves is mainly absorbed by the surface (rear direction surface H1) of the cored bar 50, which is a radiant heat destination member. This causes the temperature of the cored bar 50 to rise, but because the total mass of the cored bar 50 is sufficiently large, the temperature rise of the cored bar 50 due to heat from the substrate 31 heated by the heat generation of the first LEDs 32 and other components is not enough to be perceived as a rise in the surface temperature of the grip portion 110 by a person gripping the steering device 100. The heat radiation sheet 300 is not limited to a three-layer structure silicone sheet consisting of the heat conduction layer 311, the aluminum layer 312, and the heat radiation layer 313, and it is also acceptable to adopt a configuration in which a heat radiation paint with high emissivity is coated on an aluminum film, or a configuration in which simply a heat radiation paint with excellent heat release properties is applied.

In this steering device 100, changes in brightness and hue of the illumination region IL can be performed using the first LEDs 32 provided on the substrate 31 as a light source, or infrared light can be emitted toward the driver using the second LEDs 33. In the steering device 100 of this embodiment, since the heat radiation sheet 300 is placed in contact with the back surface of the substrate 31 accommodated in the accommodation member 40, the heat generated by the first LEDs 32 and the second LEDs 33, which are illuminated as needed, can be dissipated to the cored bar 50 using this heat radiation sheet 300. This suppresses the temperature rise of the substrate 31 and the first LEDs 32 and second LEDs 33 mounted thereon. Needless to say, if heat sources other than the first LEDs 32 and the like are mounted on the substrate 31, their heat can also be similarly dissipated to the cored bar 50.

In this embodiment, the center frequency of the infrared rays radiating from the heat radiation sheet 300 is set to a frequency at which a percentage of absorption of infrared rays having the center frequency in the substrate 31 is lower than a percentage of absorption of the infrared rays in the cored bar 50 which is a component other than the high-temperature part. As a result, the infrared rays radiating from the heat radiation sheet 300 are more absorbed by the cored bar 50, which is a component other than the substrate 31 as the high-temperature part, thereby quickly achieving heat transfer from the high-temperature part. To set the center frequency of the infrared rays radiating from the heat radiation sheet 300 as described above, a wavelength-selective heat dissipation sheet can be used. The wavelength-selective heat dissipation sheet is a sheet that sets a center frequency of electromagnetic waves radiating to the outside, when radiating heat received by heat conduction, to a predetermined frequency. Such sheets set the center frequency of radiation by forming microcavities through periodic microstructures on the heat-radiating surface. The microcavities have dimensions (length, width, and depth) of several microns and are arranged regularly. The center frequency of infrared rays radiating from the surface corresponds to the frequency range associated with the physical size and spacing of the microcavities. By matching or bringing this center frequency close to the wavelength that is more easily absorbed by the radiant heat destination member, such as the cored bar 50, than by the substrate 31 and the surrounding accommodation member 40, heat can be efficiently dissipated from the high-temperature part to the radiant heat destination member.

Moreover, in the configuration of this embodiment, there is no need to mechanically connect the substrate 31, which is expected to become a high-temperature part as a result of temperature rise due to the heat source, and the cored bar 50, which functions as the radiant heat destination member, either directly or indirectly through a heat conduction plate or the like. This allows for a high degree of freedom in the arrangement of the heat source and the radiant heat destination. Additionally, even if assembly errors occur in the arrangement of both components (in this case, the substrate 31 and the cored bar 50), the occurrence of defects due to errors can be suppressed. Arrangement errors may include positive errors where the separation distance between the two components increases and negative errors where the separation distance decreases, but since the two components are not in contact with each other to begin with, even if a positive error occurs, there will be no decrease in heat dissipation, or it will be minimal. On the other hand, even if a negative error occurs, since the two components are originally separated, there is a low risk of direct contact between them, avoiding situations where they are in a forced joined state and the substrate 31 or other components suffer physical damage.

### B. Second Embodiment

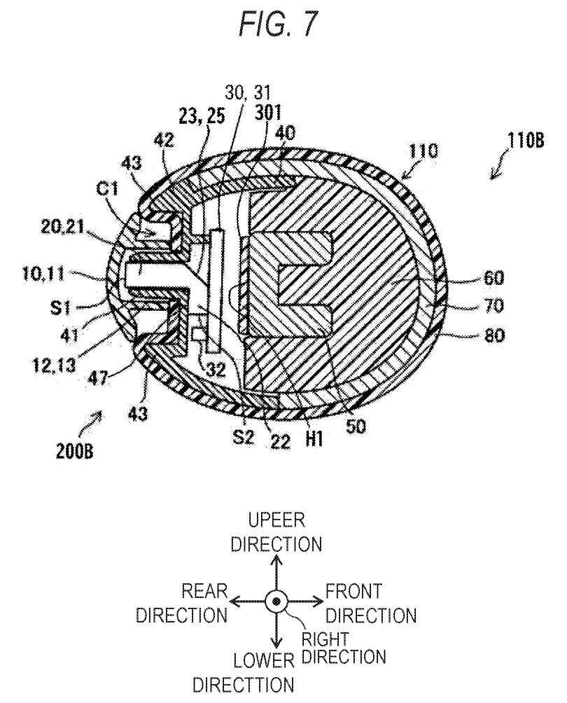

The steering device of the second embodiment and the illumination device 200B, which is an electrical component used therein, will be described. The grip portion 110B used in the steering device of the second embodiment is the same as the first embodiment except for the configuration of heat dissipation from the substrate 31 to the cored bar 50. The configuration of the grip portion 110B of the second embodiment and the illumination device 200B provided therein is shown in FIG. 7. FIG. 7 corresponds to FIG. 5 of the first embodiment and shows a cross-section of the grip portion 110B broken at the same position as in the first embodiment (see FIG. 2).

The grip portion 110B of the steering device 100 of the second embodiment differs from the first embodiment in that the heat radiation sheet 301 in the illumination device 200B is placed in contact with the rear direction surface H1 of the cored bar 50 instead of being in contact with the substrate 31. The heat radiation sheet 301 used in the second embodiment has the same three-layer structure as the heat radiation sheet 300 of the first embodiment. Like the heat radiation sheet 300 of the first embodiment, the heat radiation sheet 301 of the second embodiment is not in contact with both the substrate 31 and the cored bar 50, and heat transfer occurs by radiation. In the second embodiment, when the substrate 31 becomes hot due to the illumination and light emission of the first LEDs 32 and the second LEDs 33, electromagnetic waves radiating from the substrate 31 are efficiently captured by the heat radiation layer 313 of the heat radiation sheet 301. The captured heat is conducted from the aluminum layer 312 of the heat radiation sheet 301 to the heat conduction layer 311, and further conducted to the cored bar 50. As a result, in the second embodiment, as in the first embodiment, the temperature of the substrate 31 decreases by several to more than ten degrees compared to when there is no heat radiation sheet 300. Also, as in the first embodiment, the design freedom can be increased, and malfunctions due to dimensional accuracy errors in assembly can be reduced.

### C. Third Embodiment

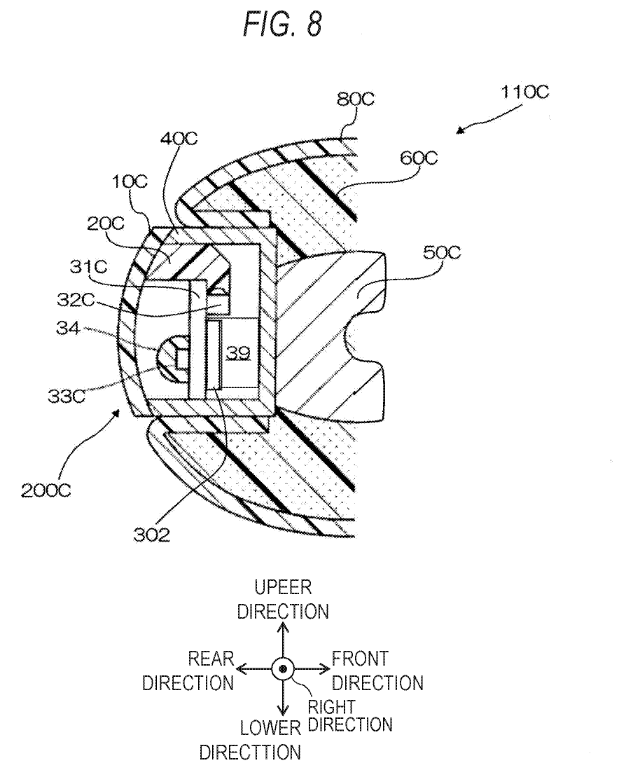

The steering device of the third embodiment will be described. FIG. 8 is an explanatory diagram showing a cross-sectional view of the main part of the grip portion 110C of the steering device of the third embodiment. The steering device of the third embodiment is the same as the first embodiment except for the configuration of the grip portion 110C. This grip portion 110C, as shown, has a cored bar 50C in the central part, which is covered by a core portion 60C around its periphery, and the outer surface of the core portion 60C is further covered by an outer skin layer 80C. A recess is provided on the rear direction of the grip portion 110C, where the accommodation member 40C of the illumination device 200C is fitted. The accommodation member 40C has an outer shape that fits into the recess, as shown in the cross-sectional view. The outer side of the bottom part (front direction side) of the accommodation member 40C is joined to the cored bar 50C when fitted into the recess. The light guiding member 20C, the substrate 31C, and other components are accommodated inside the accommodation member 40C. The rear direction side of the accommodation member 40C is open, and a cover member 10C is attached to close this opening. The outer skin layer 80C of the grip portion 110C and the cover member 10C have the same outer radius, forming a continuous cross-sectional outer shape despite having a seam.

Electronic components such as the second LEDs 33C described in the first embodiment are mounted on the surface, which is the rear direction side of the substrate 31C of the illumination device 200C. A diffusion plate 34 is attached to the second LEDs 33C to widen the infrared radiation range. Electronic components such as the first LEDs 32C are mounted on the back surface of the substrate 31C, as in the first embodiment. The first LEDs 32C are attached so that their light-emitting parts are housed in recesses formed at the lower end of the light guiding member 20C. The substrate 31C is held against the bottom of 40C by spacers 39.

A heat radiation sheet 302 having the same material and configuration as that used in the first embodiment is attached to the back surface of the substrate 31C. In FIG. 8, for convenience of illustration, the heat radiation sheet 302 is depicted as not overlapping with the first LEDs 32C, but the heat radiation sheet 302 may be arranged to cover the first LEDs 32C.

In the steering device with such a grip portion 110C and the illumination device 200C used therein, as in the first embodiment, the substrate 31C becomes hotter than the surrounding areas without light sources due to heat generation from the first LEDs 32C and the second LEDs 33C. However, heat from the substrate 31C, which is the high-temperature part, is conducted to the heat radiation sheet 302 and radiates as electromagnetic waves (infrared rays) from the outer surface of the heat radiation sheet 302. The infrared rays radiating from the heat radiation sheet 302 are absorbed by the bottom of the accommodation member 40C, increasing its temperature, but the heat from the bottom of the accommodation member 40C eventually transfers to the cored bar 50C. As a result, the temperature of the substrate 31C decreases compared to when there is no heat radiation sheet 302, as in the first embodiment. Other advantages, such as freedom in the arrangement of electronic components that become hot and benefits regarding dimensional errors, are also the same as in the first embodiment.

### D. Fourth Embodiment

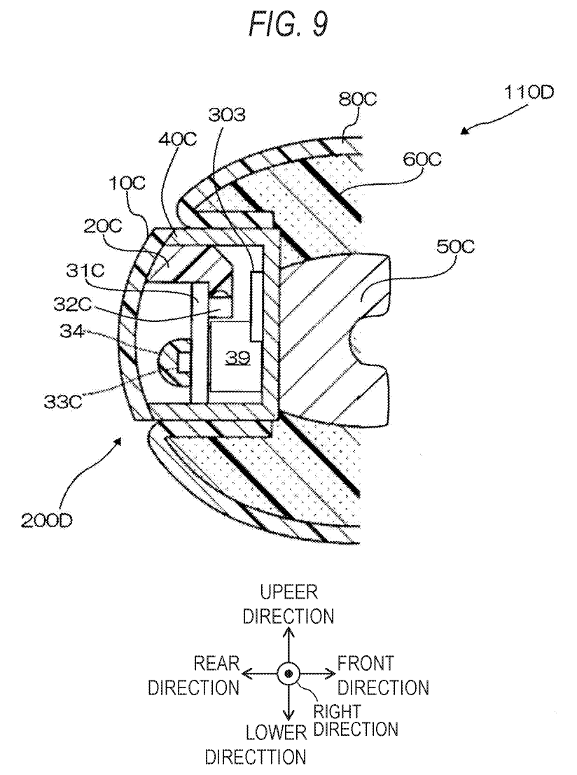

The steering device of the fourth embodiment and the illumination device 200D used therein will be described. FIG. 9 is an explanatory diagram showing a cross-sectional view of the main part of the grip portion 110D of the steering device of the fourth embodiment. The grip portion 110D used in the steering device of the fourth embodiment is almost identical to the grip portion 110C of the third embodiment shown in FIG. 8, except for the arrangement of the heat radiation sheet. Therefore, the description of parts other than the heat radiation sheet 303 is omitted.

In the fourth embodiment, the heat radiation sheet 303 is provided on the inner bottom portion of the accommodation member 40C, rather than on the back surface of the substrate 31C. In this embodiment, the heat radiation sheet 303 is fixed to the bottom of the accommodation member 40C with adhesive. The fixing method may be by other means such as screws. The heat radiation sheet 303 may cover the entire inner bottom portion of the accommodation member 40C or may cover only a part of it.

In the steering device and illumination device 200D with the grip portion 110D of such configuration, as in the second embodiment, the substrate 31C becomes hotter than the surrounding areas without these heat-generating components due to heat generation from the first LEDs 32C and the second LEDs 33C. However, electromagnetic waves (infrared rays) radiating from the substrate 31C, which is the high-temperature part, are absorbed by the heat radiation sheet 303 provided at the bottom of the accommodation member 40C, and the absorbed heat is conducted through the accommodation member 40C and eventually to the cored bar 50C. As a result, the temperature of the substrate 31C decreases compared to when there is no heat radiation sheet 303, as in the second embodiment. Other advantages, such as freedom in the arrangement of electronic components that become hot and benefits regarding dimensional errors, are also the same as in the second embodiment.

### E. Fifth Embodiment

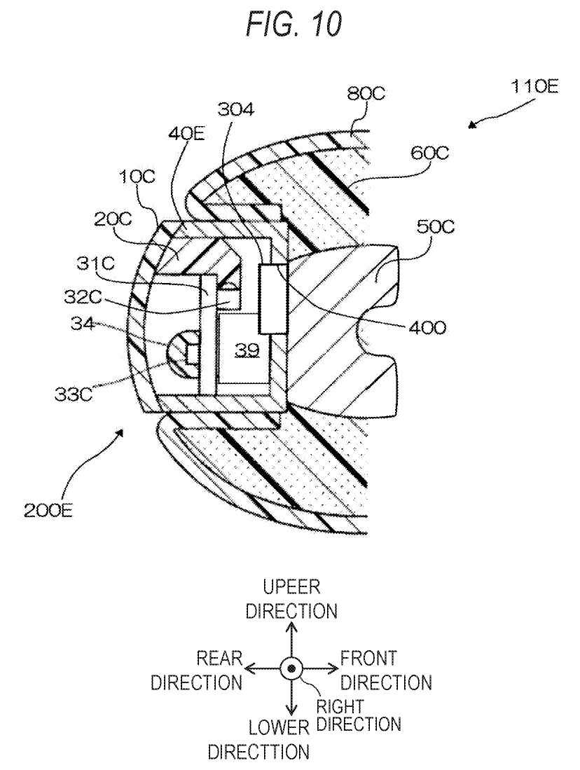

The fifth embodiment will be described. FIG. 10 is an explanatory diagram showing a cross-sectional view of the main part of the grip portion 110E used in the steering device of the fifth embodiment. In the fifth embodiment, as in the fourth embodiment, the heat radiation sheet 304 is placed at the bottom of the accommodation member 40D of the illumination device 200E, but in this embodiment, an opening 400 is provided in the bottom of the accommodation member 40D, and the heat radiation sheet 304 is placed in the opening 400 and directly fixed to the cored bar 50C with adhesive. This allows heat that has transferred by radiation from high-temperature parts such as the substrate 31C to be efficiently dissipated to the cored bar 50C by heat conduction. Other effects are the same as in the fourth embodiment.

### F. Other Embodiments

(1) The present disclosure can be implemented as an electrical component having a high-temperature part that reaches a predetermined temperature or higher. The electrical component has an accommodation member that accommodates the high-temperature part, and a heat radiation sheet that transfers heat from the high-temperature part, by radiation, to an outside of the accommodation member. Any type of electrical component may be used as long as it has a high-temperature part requiring heat dissipation. For example, it can be applied to various electrical components used in moving bodies such as two-wheeled vehicles, four-wheeled vehicles, trains, ships, etc. For example, it can be applied to various electrical components such as a steering device with an illumination device, an instrument panel, an electronic control unit for vehicle control, an inverter used for power conversion in the moving body, etc. Various accommodation members such as metallic or resin-made can be used, but there is an advantage of increased design freedom especially when the tolerance range for dimensional errors in assembly between the accommodation member and the high-temperature part is narrow, or when there are significant constraints in designing a heat conduction path to transfer heat to the outside.
(2) In the above configuration, the electrical component may further has a radiant heat destination member to which the heat to be transferred to the outside of the accommodation member is transferred. The heat radiation sheet may be arranged in contact with either the high-temperature part or the radiant heat destination member. The radiant heat destination member may be a frame provided in the moving body or a member (for example, a cored bar) that forms a skeleton of a device in which the electrical component is mounded. The heat radiation sheet contacts either the high-temperature part or the radiant heat destination member, but not both. This ensures high design freedom regarding the arrangement of the high-temperature part and the radiant heat destination member.
(3) In the configuration of (1) or (2), the heat radiation sheet may be arranged in contact with the high-temperature part, and heat from the high-temperature part may be dissipated outside the accommodation member by infrared rays radiating from the heat radiation sheet. Such a configuration can be easily realized by, for example, constructing a part of the accommodation member with a material that can transmit infrared rays radiating from the heat radiation sheet. In this case, if a material that transmits infrared rays but not visible light is selected, heat can be dissipated to the outside even though the inside of the accommodation member is not visible.
(4) In the configuration of (1) to (3), the high-temperature part may be a light-emitting element that emits visible light, infrared rays, or both the visible light and the infrared rays. Various light-emitting elements such as LEDs, organic ELs, discharge lamps, etc. can be adopted. These light-emitting elements, even when selecting those with high emission efficiency, have surplus energy other than light in the emission process, which increases the temperature of the light-emitting element and nearby components as heat, forming a high-temperature part. In other words, a high-temperature part refers to an area that becomes higher in temperature compared to the surroundings of the heat source. Light-emitting elements are used as light sources to extract light to the outside, but they may also be used for communication within electronic components. Even in this case, the temperature of the light-emitting element and its surroundings increases, forming a high-temperature part.
(5) In the configuration of (1) to (4), the heat radiation sheet may be a wavelength-selective heat dissipation sheet in which a center frequency of the infrared rays radiating from the wavelength-selective heat dissipation sheet is set to a predetermined frequency. To set the center frequency of electromagnetic waves radiating from the wavelength-selective heat dissipation sheet to a predetermined frequency, if the sheet is of a type that forms micro-cavities with periodic microstructures on its surface, the physical size and spacing of the micro-cavities can be adjusted. Alternatively, if the sheet is of a type with heat-dissipating paint applied to the heat-radiating side, the composition of the heat-dissipating paint can be adjusted. If this center frequency matches or approaches the wavelength that is easily absorbed by the radiant heat destination member such as the cored bar, heat from the high-temperature part can be efficiently dissipated to the radiant heat destination member.
(6) In the configuration of (1) to (5), the center frequency of the infrared rays may be a frequency at which a percentage of absorption of infrared rays having the frequency in the high-temperature part is lower than a percentage of absorption of the infrared rays in members other than the high-temperature part. This ensures that the infrared rays radiating from the heat radiation sheet are absorbed by the members other than the high-temperature part, enabling prompt transfer of heat from the high-temperature part. The degree of the percentage of absorption of the infrared ray can be compared by the amount of heat absorption per unit volume or the amount of heat absorption per unit time. Additionally, if the heat radiation sheet is covered with a cover member that has high transmittance for the center frequency region of infrared rays radiating from the heat radiation sheet and lower transmittance for visible light, heat from the heat radiation sheet can be released to the outside through the cover member, while making the internal heat radiation sheet less visible from the outside.
(7) In a steering device having an electrical component having any one of the configurations of (1) to (6) and a handle portion for steering operation, the accommodation member may constitute a part of the handle portion. This makes it easier to radiate heat from the high-temperature part to outside the handle portion. In particular, it is also preferable that the accommodation member constituting a part of the handle portion covers the heat radiation sheet, and this accommodation member has high transmittance for the center frequency region of infrared rays radiating from the heat radiation sheet and lower transmittance for visible light. This way, the heat from the heat radiation sheet can be released to the outside air through a part of the handle portion functioning as the accommodation member, while making the internal heat radiation sheet less visible from the outside.

The present disclosure is not limited to the above-described embodiments and can be realized in various configurations without departing from its spirit. For example, technical features in the embodiments corresponding to the technical features in the aspects described in the summary of the invention can be replaced or combined as appropriate to solve a part or all of the above-described problems or to achieve a part or all of the above-described effects. Also, if the technical feature is not described as essential in this specification, it can be appropriately deleted. For example, a part of the configuration realized by hardware in the above embodiments can be realized by software.

What is claimed is:

1. An electrical component having a high-temperature part that reaches a predetermined temperature or higher, the electrical component comprising:
an accommodation member that accommodates the high-temperature part; and
a heat radiation sheet that transfers heat from the high-temperature part, by radiation, to a radiant heat destination member different from the accommodation member.

2. The electrical component according to claim 1, wherein
the heat radiation sheet is arranged in contact with either the high-temperature part or the radiant heat destination member.

3. The electrical component according to claim 1, wherein
the heat radiation sheet is arranged in contact with the high-temperature part, and
heat from the high-temperature part is dissipated outside the accommodation member by infrared rays radiating from the heat radiation sheet.

4. The electrical component according to claim 1, wherein
the high-temperature part is a light-emitting element that emits visible light, infrared rays, or both the visible light and the infrared rays.

5. The electrical component according to claim 1, wherein
the heat radiation sheet is a wavelength-selective heat dissipation sheet in which a center frequency of infrared rays radiating from the wavelength-selective heat dissipation sheet is set to a predetermined frequency.

6. The electrical component according to claim 5, wherein
the center frequency of the infrared rays is a frequency at which a percentage of absorption of infrared rays having the frequency in the high-temperature part is lower than a percentage of absorption of the infrared rays in members other than the high-temperature part.

7. A steering device comprising:
a handle portion for steering operation; and
the electrical component according to claim 1,
wherein the radiant heat destination member constitutes a part of the handle portion.
